(19) United States
(12) Patent Application Publication
(10) Pub. No.: US 2015/0362810 A1
(43) Pub. Date: Dec. 17, 2015

(54) ARRAY SUBSTRATE AND MANUFACTURING METHOD THEREOF, AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Jiaxiang ZHANG, Beijing (CN); Jian GUO, Beijing (CN); Xiaohui JIANG, Beijing (CN)

(21) Appl. No.: 14/499,486

(22) Filed: Sep. 29, 2014

(30) Foreign Application Priority Data
Jun. 16, 2014 (CN) 201410267069.0

(51) Int. Cl. G02F 1/1362; H01L 27/12; H01L 23/522; H01L 23/528; H01L 29/24; G02F 1/1335; H01L 21/46; H01L 21/441; H01L 21/768; G02F 1/1368; G02F 1/1333; H01L 29/786; H01L 29/66

(52) U.S. Cl. CPC G02F 1/136286; H01L 29/7869; H01L 27/124; H01L 27/1248; H01L 23/5226; H01L 23/528; H01L 29/24; H01L 29/66969; H01L 27/127; H01L 21/46; H01L 21/441; H01L 21/76895; H01L 27/1259; H01L 27/1225; G02F 1/1368; G02F 1/133345; G02F 1/136227; G02F 1/133514; G02F 2001/13629; G02F 2001/136295

(57) ABSTRACT

The present invention discloses an array substrate, comprising a substrate and common signal lines arranged on the substrate. The common signal lines comprise a first common signal line and a second common signal line which are spaced from each other; a first active layer is arranged between the first common signal line and the second common signal to form a first switch transistor; and the second common signal line is connected to a common electrode arranged above the second common signal line. A gate and a second active layer are sequentially arranged above the first active layer; a source signal line and a drain signal line are arranged on the second active layer to form a second switch transistor, and the drain signal line is connected to a pixel electrode arranged above the drain signal line.

### FIELD OF THE INVENTION

The present invention relates to the field of display technology, and particularly to an array substrate and a manufacturing method thereof, and a display device.

### BACKGROUND OF THE INVENTION

Recently, consumers have increasing requirements on the resolution, contrast, angle of view and response time at to display, particulary on high PPI (Pixels Per Inch). In order to meet the requirements of consumers, practitioners associated with displays successively throw themselves into the development of blue-phase liquid crystal displays having quick response characteristics. Blue-phase liquid crystal molecules have higher dielectric constants and require larger driving voltage to realize effective driving.

In existing array substrates, a pixel voltage is transferred to a pixel electrode via a driving chip, a common voltage on a common electrode is set as a predetermined voltage, and a difference value between the pixel voltage and the predetermined voltage forms a driving voltage for a display medium (generally using liquid crystals as the medium). However, because the common voltage is generally a fixed value, in order to enable the driving voltage to alternate between positive and negative levels, the maximum driving voltage is only a half of the maximum voltage difference transferred by the driving chip. For example, the common voltage is 0V and the pixel voltage is switched between +5V and −5V to realize alternation between positive and negative, the maximum voltage difference transferred by the driving chip is a difference value between +5V and −5V, i.e., 10V, and a difference value between the common voltage and the positive value or the negative value of the pixel voltage is the driving voltage. Whether the pixel voltage is +5V or −5V, the difference value between the pixel voltage and the common voltage is 5 V. It is this obvious that the maximum driving voltage is only a half of the maximum voltage difference transferred by of the driving chip.

It can be seen from the above that, in an existing array substrate, the common voltage is a preset fixed value, and therefore the maximum driving voltage is only a half of the maximum voltage difference on the pixel electrode, that is, the driving voltage provided by the existing array substrate is limited. For liquid crystal displays (e.g., blue-phase liquid crystal displays) requiring large voltage for driving, the driving voltage provided to rotate liquid crystals by the existing array substrate is limited and cannot meet the demand.

### SUMMARY OF THE INVENTION

### (1) Technical Problem to be Solved

A technical problem to be solved by the present invention is how to provide a larger driving voltage for an array substrate to realize effective driving, so as to overcome the disadvantage that the driving voltage is insufficient in the prior art.

### (2) Technical Solutions

To solve the above technical problem, the present invention provides an array substrate, including a substrate and common signal lines arranged on the substrate, wherein the common signal lines includes a first common signal line and a second common signal line which are spaced from each other, a first active layer for connecting the first common signal line and the second common signal line is arranged between the first common signal line and the second common signal line and on the first common signal line and the second common signal line, the second common signal line is connected to a common electrode arranged above the second common signal line; and

a gate and a second active layer are sequentially arranged above the first active layer, a source signal line and a drain signal line are arranged on the second active layer, and the drain signal line is connected to a pixel electrode arranged above the drain signal line

Further, a first insulating layer is furthet arranged on the first active layer and beneath the gate.

Further, a second insulating,layer is further arranged on the gate and beneath the second active layer, a first via is arranged at positions of the first insulating layer and the second insulating layer corresponding to the second common signal line, and the second common signal line is connected to the common electrode through the first via.

Further, a third insulating layer is further arranged on the source signal line and the drain signal line, a second via is arranged at a position of the third insulating layer corresponding to the drain signal line, and the drain signal line is connected to the pixel electrode through the second via.

Further, the common electrode is plate-shaped or strip-shaped, and the pixel electrode is strip-shaped.

Further, an etching barrier layer is arranged on the second active layer and beneath the source signal line and the drain signal line, and the etching barrier layer covers the middle part of the second active layer.

Further, both the first active layer and the second active layer are oxide semiconductor layers.

To solve the above technical problem, the present invention further provides a manufacturing method of an array substrate, including steps of:

forming common signal lines on a substrate, wherein the common signal lines include a first common signal line and a second common signal line which are spaced from each other;

forming a first active layer between the first common signal line and the second common signal line, wherein the first active layer is used for connecting the first common signal line and the second common signal line;

sequentially forming a first insulating layer, a gate and a second insulating layer above the first active layer;

forming as second active layer above the gate;

forming an etching barrier layer on the second active layer;

forming a first via at positions of the first insulating layer and the second insulating layer corresponding to the second common signal line;

forming a common electrode on the second insulating layer, wherein the common electrode is connected to the second common signal line through the first via; and

forming a source signal line and a drain signal line on the etching barrier layer.

Further, after the step of forming the source signal line and the drain signal line, the method further comprises steps of:

forming a third insulating layer on the source signal line and the drain signal line, and forming a second via at a position of the third insulating layer corresponding to the drain signal line; and

forming a pixel electrode on the third insulating layer, wherein the pixel electrode is connected to the drain signal line through the second via.

To solve the above technical problem, the present invention further provides a display device, including a color filter substrate, an array substrate and a liquid crystal layer filled between the color filter substrate and the array substrate, wherein the array substrate is the above-mentioned array substrate.

### (3) Advantages

The array substrate provided by embodiments of the present invention includes a substrate and common signal lines arranged on the substrate, wherein the common signal lines includes a first common signal line and a second common signal line which are spaced from each other, a first active layer is arranged between the first common signal line and the second common signal line to form a first switch transistor, the second common signal line is connected to a common electrode arranged above the second common signal line; and a gate and a second active layer are sequentially arranged above the first active layer, a source signal line and a drain signal line are arranged on the second active layer to form a second switch transistor, and the drain signal line is connected to a pixel electrode arranged above the drain signal line. A data signal line is connected to the pixel electrode through the second switch transistor to provide a pixel voltage, and the common signal line is connected to the common electrode through the first switch transistor to provide a common voltage. Therefore, the common voltage provided by the common signal line may be adjusted according to use requirements, and a larger voltage difference between the pixel voltage and the common voltage can be thus obtained, so that a driving voltage larger than the driving voltage of the existing array substrate is realized without changing a driving chip, so as to realize large-voltage driving. As the common signal lines and the data signal line share one gate, the pixel voltage and the common voltage of a single sub-pixel may be simultaneously input by the gate without increasing the aperture ratio, so as to provide a driving voltage meeting the requirements of a user, thus overcoming the deficiency that the driving voltage is limited in the prior art. Meanwhile, both the manufacturing method of an array substrate provided by the present invention and the display device including the above-mentioned array substrate also have the above advantages.

### BRIEF DESCRIPTION OF THE DRAWINGS

FIG. 1 is a plan schematic diagram of an array substrate provided by Embodiment 1 of the present invention;

FIG. 2 is a sectional schematic diagram of the array substrate in FIG. 1 in a direction of A-A′;

FIG. 3 is a sectional schematic diagram of the array substrate in FIG. 1 in a direction of B-B′;

FIG. 4 is a flowchart of steps of a manufacturing method of an array substrate provided by Embodiment 2 of the present invention;

FIG. 5 is a sectional schematic diagram of a portion of the array substrate shown in FIG. 1 in the direction of A-A′, wherein the portion is obtained after a first pattern in process;

FIG. 6 is a sectional schematic diagram of a portion of the array substrate shown in FIG. 1 in the direction of B-B′, wherein the portion is obtained after the first patterning process;

FIG. 7 is a sectional schematic diagram of a portion of the array substrate shown in FIG. 1 in the direction of A-A′, wherein the portion is obtained after a second patterning process;

FIG. 8 is a sectional schematic diagram of a portion of the array substrate shown in FIG. 1 in the direction of B-B′, wherein the portion is obtained after the second patterning process;

FIG. 9 is a sectional schematic diagram of a portion of the array substrate shown in FIG. 1 in the direction of A-A′, wherein the portion is obtained after a third patterning process;

FIG. 10 is a sectional schematic diagram of a portion of the array substrate shown in FIG. 1 in the direction of B-B′, wherein the portion is obtained after the third patterning process;

FIG. 11 is a sectional schematic diagram of a portion of the array substrate shown in FIG. 1 in the direction of A-A′, wherein the portion is obtained after a fourth patterning process;

FIG. 12 is a sectional schematic diagram of a portion of the array substrate shown in FIG. 1 in the direction of B-B′, wherein the portion is obtained after the fourth patterning process;

FIG. 13 is a sectional schematic diagram of a portion of the array substrate shown in FIG. 1 in the direction of A-A′, wherein the portion is obtained after a fifth patterning process;

FIG. 14 is a sectional schematic diagram of a portion of the array substrate shown in FIG. 1 in the direction of B-B′, wherein the portion is obtained after the fifth patterning process;

FIG. 15 is a sectional schematic diagram of a portion of the array substrate shown in FIG. 1 in the direction of B-B′, wherein the portion is obtained after a sixth patterning process;

FIG. 16 is a sectional schematic diagram of a portion of the array substrate shown in FIG. 1 in the direction of B-B′, wherein the portion is obtained after a seventh patterning process;

FIG. 17 is a sectional schematic diagram of a portion of the array substrate shown in FIG. 1 in the direction of A-A′, wherein the portion is obtained after an eighth patterning process;

FIG. 18 is a sectional schematic diagram of a portion of the array substrate shown in FIG. 1 in the direction of A-A′, wherein the portion is obtained after a ninth patterning process; and

FIG. 19 is a sectional schematic diagram of a portion of the array substrate shown in FIG. 1 in the direction of B-B′, wherein the portion is obtained after the ninth patterning process.

### REFERENCE NUMERALS

1—Substrate; 2—Common signal lines; 21—First common signal line; 22—Second common signal line: 3—First active layer: 4—First insulating layer; 5—Gate; 6—Second insulating layer; 7—Data signal line; 71—Source signal line; 72—Drain signal line; 8—Second active layer; 9—Etching barrier layer; 10—Third active layer; 11—Common electrode; 12—Pixel electrode; 13—First via; and, 14—Second via.

### DETAILED DESCRIPTION OF THE EMBODIMENTS

Specific implementations of the present invention will be further illustrated in detail below in connection with the accompanying figures and embodiments. The following embodiments are used to explain the present invention but not to limit the present invention.

### Embodiment 1

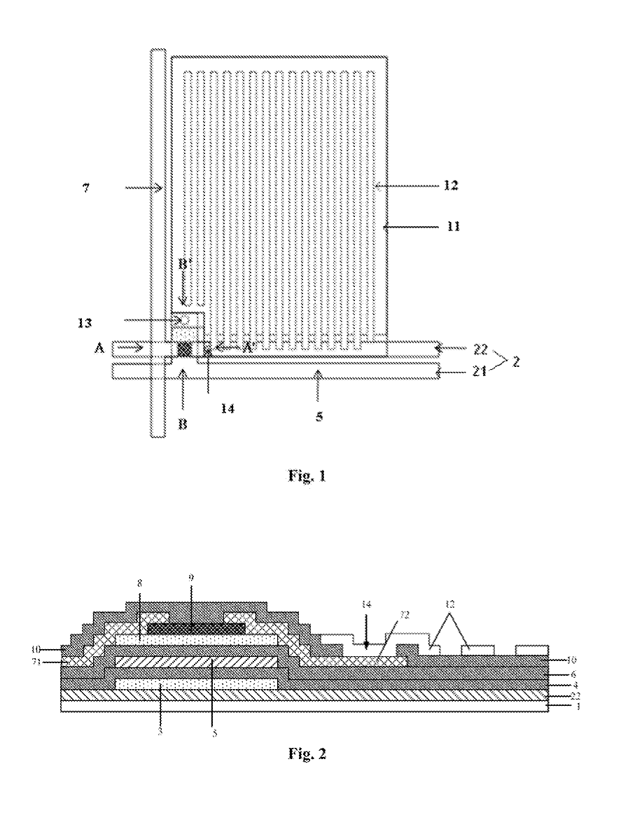

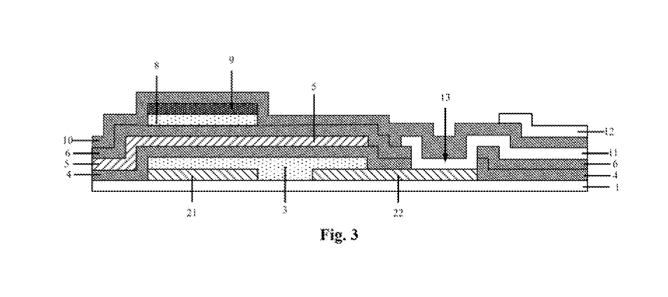

Embodiment 1 of the present invention provides an array substrate, as shown in FIGS. 1-3, wherein FIG. 1 is a plan schematic diagram of an array substrate in Embodiment 1, and FIG. 2 and FIG. 3 are sectional schematic diagrams of the array substrate of FIG. 1 in a direction of A-A′ and in a direction of B-B′, respectively. The array substrate includes a substrate 1 (not shown in FIG. 1) and common signal lines 2 arranged on the substrate 1. The common signal lines 2 include a first common signal line 21 and a second common signal line 22 which are spaced from each other. A first active layer 3 is arranged between the first common signal line 21 and the second common signal line 22 so as to form a first switch transistor. The second common signal line 22 is connected to a common electrode 11 arranged above the second common signal line 22.

A gate 5 and a second active layer 8 are sequentially arranged above the first active layer 3. A source signal line 71 and a drain signal line 72 are further arranged on the second active layer 8 so as to form a second switch transistor. The drain signal line 72 is connected to a pixel electrode 12 arranged above the drain signal line 72.

In addition, in FIG. 1, a first via 13 and a second via 14 are also included. The second common signal line 22 is connected to the common electrode 11 through the first via 13 (as shown in FIG. 3), and the drain signal line 72 is connected to the pixel electrode 12 through the second via 14 (as shown in FIG. 2).

For the array substrate in FIG. 1, the sectional schematic diagram in the direction of A-A′ is as shown in FIG. 2, and the sectional schematic diagram in the direction of B-B′ is as shown in FIG. 3. Referring to FIGS. 2 and 3, in addition to the substrate 1, the first common signal line 21, the second common signal line 22, the first active layer 3, the gate 5, the source signal line 71, the drain signal line 72, the second active layer 8, the common electrode 11, the pixel electrode 12, the first via 13 and the second via 14, the array substrate further includes a first insulating layer 4, a second insulating layer 6, an etching barrier layer 9 and a third insulating layer 10.

Specifically, the first insulating layer 4 is arranged on the first active layer 3 and beneath the gate 5. It should be noted that the first active layer 3 in this embodiment is an oxide active layer, and a first switch transistor may be formed by the oxide active layer between the first common signal line 21 and the second common signal line 22. As the second common signal line 22 is also connected to the common electrode 11 through the first via 13, a common voltage can be provided to the common electrode 11 through the second common signal line 22 when the first switch transistor is turned on.

Specifically, the second insulating layer 6 is arranged on the gate 5 and beneath the second active layer 8, the first via 13 is arranged at a position of the first insulating layer 4 and the second insulating layer 6 corresponding to the second common signal line 22, and the second common signal line 22 is connected to the common electrode 11 through the first via 13. The common electrode 11 is arranged above the second common signal line 22. Specifically, the common electrode 11 is arranged on the second insulating layer 6 and beneath the third insulating layer 10 but is not connected to the second active layer 8.

Specifically, the etching barrier layer 9 is arranged beneath the source signal line 71 and the drain signal line 72, and the etching barrier layer 9 covers the middle part of the second active layer 8, so that the source signal line 71 and the drain signal line 72 are electrically connected to the second active layer 8, respectively, at the edges of the etching barrier layer 9. Referring to FIG. 2, although manufactured in the same layer, the source signal line 71 and the drain signal line 72 are spaced from each other. After a source-drain metal layer is formed on the etching barrier layer 9, the source-drain metal layer is etched. In the process of etching the source-drain metal layer, the etching barrier layer 9 may protect the second active layer 8 therebeneath from being damaged by etching.

Specifically, the third insulating layer 10 is arranged on the common electrode 11 and on the source signal line 71 and the drain signal line 72, the second via 14 is arranged at as position of the third insulating layer 10 corresponding to the drain signal line 72, and the drain signal line 72 is connected to a pixel electrode 12 arranged above the drain signal line 72 (specifically, arranged on the third insulating layer 10) through the second via 14. The array substrate in this embodiment may be applied to ADS (Advanced super Dimension Switch) type panels, the common electrode 11 is plate-shaped or strip-shaped, and the pixel electrode 12 is strip-shaped. Referring to FIG. 1, the pixel electrodes 12, in a strip shape, are uniformly distributed in a pixel region. However, when the common electrode 11 is located outside the pixel region (referring to FIG. 2), the common electrode 11 connected to the drain signal line 72 is of a plate-shaped structure, and the strip-shaped pixel electrode 12 in FIG. 2 is located in the pixel region.

It should also be noted that, both the first active layer 3 and the second active layer 8 in this embodiment are preferably oxide active layers, an oxide active layer is used as a switch between the first common signal line 21 and the second common signal line 22 to form a first switch transistor, and on and off of the electrical connection between the first common signal line 21 and the second common signal line 22 which are spaced from each other are realized by controlling the active layer; similarly, an oxide active layers is used as a switch between the source signal line 71 and the drain signal line 72 to form a second switch transistor, and on and off of the electrical connection between the source signal line 71 and the drain signal line 72 which are spaced from each other may also be realized by controlling the active layers. In addition, the first active layer 3 and the second active layer 8 may also be silicide active layers. However, portions of the suicide active layer near the first common signal line 21, the second common signal line 22, the source signal line 71 and the drain signal line 72 need to be ion-doped, so that on and off of the electrical connection between the first common signal line 21 and the second common signal line 22 and on and off of the electrical connection between the source signal line 71 and the drain signal line 72 can be realized by the active layers. Here, the type and amount of doped ions may be designed according to specific requirements and will not be repeated here.

The working principle of the array substrate is as follows:

When a turn-on voltage is applied to the gate 5, the first active layer 3 below the gate 5 is in an on state, and the electrical connection between the first common signal line 21 and the second common signal line 22 is turned on. As the second common signal line 22 is connected to the common electrode 11 through the first via 13, the second common signal line 22 begins to provide a common voltage to the common electrode 11.

When the turn-on voltage is applied to the gate 5, the second active layer 8 above the gate 5 is also in an on state, and the electrical connection between the source signal line 71 and the drain signal line 72 is also turned on. As the data signal line 7 is connected to the source signal line 71, and the drain signal line 72 is connected to the pixel electrode 12 through the second via 14, the data signal line 7 may provide a pixel voltage to the pixel electrode 12 when the second active layer 8 is in the on state. When a cut-off voltage is applied to the gate 5, the first active layer 3 and the second active layer 8 are cut off simultaneously, and the voltage values of the common voltage and the pixel voltage are maintained.

By adopting the design in this embodiment, the problem that the driving voltage is limited as the existing common voltage is a set fixed value may be avoided, the value of the common voltage may be changed according to the requirements, and the large-voltage driving is achieved without changing the pixel voltage (i.e., the specification of the driving chip). For example, the pixel voltage is still +5V and −5V, but the common voltage is not a fixed 0V any more. When the pixel voltage is +5V, the provided common voltage is −5V, and the obtained voltage difference is 10V, so that a large driving voltage having a voltage difference of 10 V, rather than a driving voltage of 5V, may be obtained. Therefore, the driving voltage is not limited by the fixed common voltage any more.

In conclusion, in the array substrate provided in this embodiment, the data signal line 7 is connected to the pixel electrode 12 through the second switch transistor to provide the pixel voltage, and the common signal line 2 is connected to the common electrode 11 through the first switch transistor to provide the common voltage, so a larger voltage difference between the pixel voltage and the common voltage can be obtained by adjusting the common voltage provided by the common signal line 2 according to the use requirements, and a driving voltage larger than the driving voltage of the existing array substrate is realized without changing the driving chip, so as to realize large-voltage driving. As the common signal lines 2 and the data signal line 7 share one gate 5, the pixel voltage and the common voltage of a single sub-pixel may be input simultaneously through the gate without increasing the aperture ratio 5, so as to provide a driving voltage meeting the requirements of a user, and to overcome the deficiency that the driving voltage is limited in the prior art.

### Embodiment 2

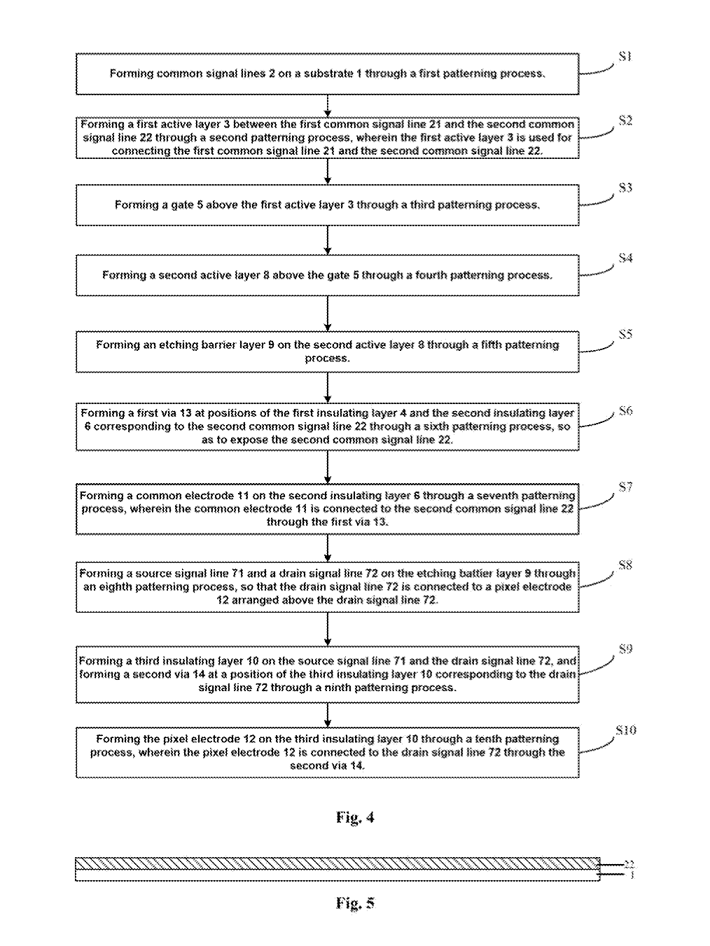

Embodiment 2 of the present invention provides a manufacturing method of an array substrate. The flowchart of the manufacturing method is as shown in FIG. 4, and specifically includes steps S1-S8.

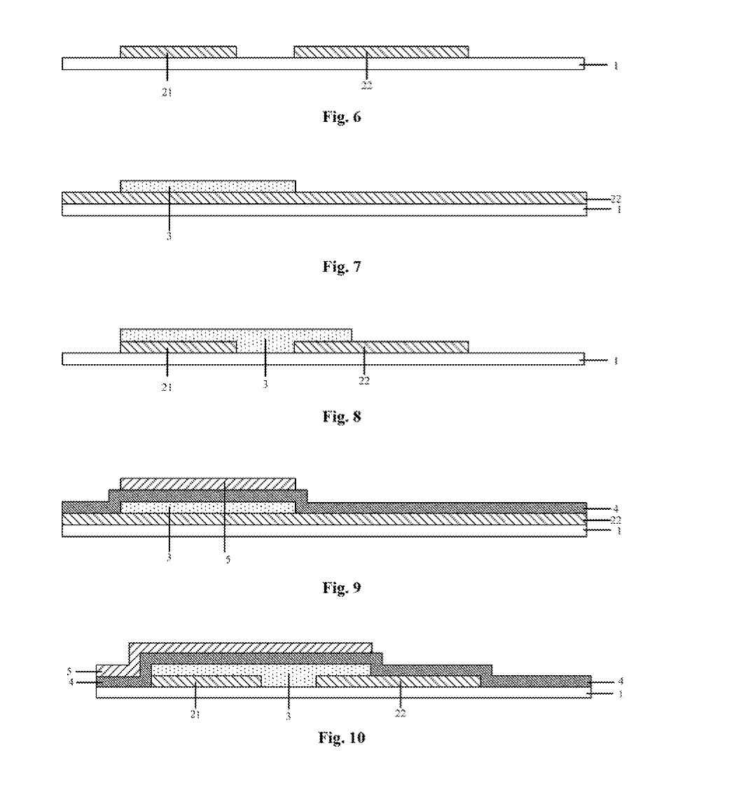

S1: Depositing a metal layer on a substrate 1, and forming common signal lines 2 on the substrate 1 through a first patterning process, wherein the common signal lines 2 include a first common signal line 21 and a second common signal line 22 which are spaced from each other. The sectional schematic diagrams of the obtained array substrate in the direction of A-A′ and in the direction of B-B′ are as shown in FIG. 5 and FIG. 6, respectively.

S2: Depositing a semiconductor layer on the common signal lines 2, and forming a first active layer 3 between the first common signal line 21 and the second common signal line 22 through a second patterning process, wherein the first active layer 3 is used for connecting the first common signal line 21 and the second common signal line 22. The sectional schematic diagrams of the obtained array substrate in the direction of A-A′ and in the direction of B-B′ are as shown in FIG. 7 and FIG. 8, respectively.

After the first active layer 3 is obtained in the second patterning process in S2 and before a metal layer is deposited to form a gate 5 in S3, the manufacturing method further includes a step of: depositing an insulating layer on the first active layer 3 to form a first insulating layer 4.

S3: Depositing a metal layer above the first active layer 3, and forming a gate 5 through a third patterning process. The sectional schematic diagrams of the obtained array substrate in the direction of A-A′ and in the direction of B-B′ are as shown in FIG. 9 and FIG. 10, respectively.

After the gate 5 is obtained through the third patterning process and before a second active layer 8 is formed in S4, the manufacturing method further includes a step of: depositing an insulating layer on the gate 5 to form a second insulating layer 6.

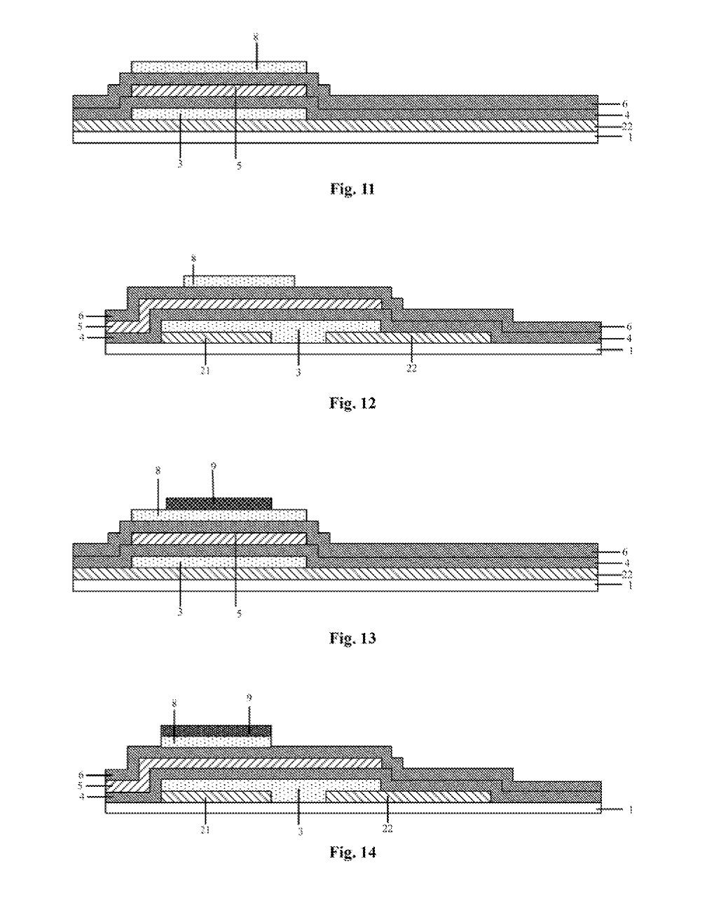

S4: Depositing a semiconductor layer above the gate 5, and forming a second active layer 8 above the gate 5 through a fourth patterning process. Specifically, the second active layer 8 is formed at a position of the second insulating layer 6 corresponding to the gate 5. The sectional schematic diagrams of the obtained array substrate in the direction of A-A′ and in the direction of B-B′ are as shown in FIG. 11 and FIG. 12, respectively.

S5: Depositing an insulating layer on the second active layer 8, forming an etching barrier layer 9 on the second active layer 8 through a fifth patterning process, so that the etching barrier layer 9 only covers the middle part of the second active layer 8 but does not cover two ends of the second active layer 8, wherein the etching barrier layer 9 is used for protecting the second active layer 8 from being damaged in the process of etching a source-drain metal layer. The sectional schematic diagrams of the obtained array substrate in the direction of A-A′ and in the direction of B-B′ are as shown in FIG. 13 and FIG. 14, respectively.

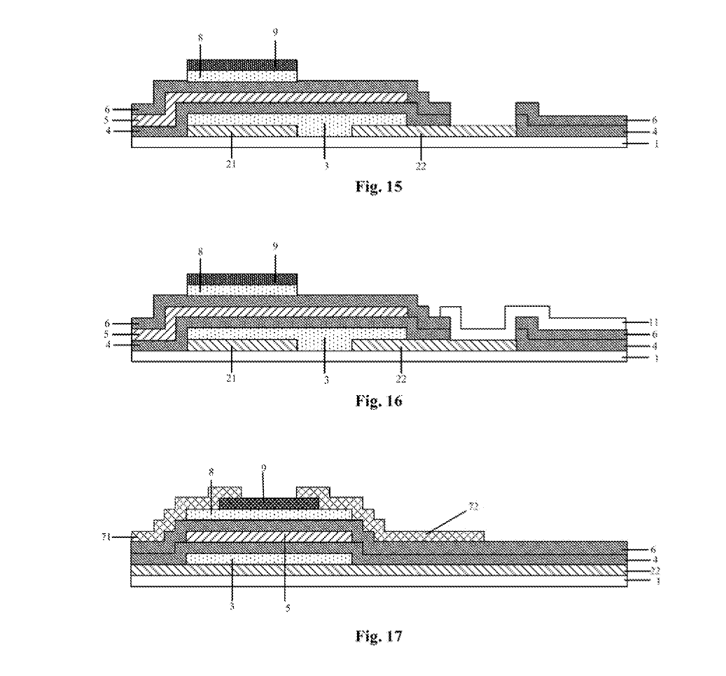

S6: Forming a first via 13 at positions of the first insulating layer 4 and the second insulating layer 6 corresponding to the second common signal line 22 through a sixth patterning process, so as to expose the second common signal line 22. The sectional schematic diagram of the obtained array substrate in the direction of A-A′ remains unchanged in comparison with FIG. 13, while the sectional schematic diagram in the direction of B-B′ is as shown in FIG. 15.

S7: Depositing a metal layer on the second insulating layer 6, and forming a common electrode 11 on the second insulating layer 6 through a seventh patterning process, wherein the common electrode 11 is not connected to the second active layer 8, and the common electrode 11 is connected to the second common signal line 22 through the first via 13. The sectional schematic diagram of the obtained array substrate in the direction of A-A′ still remains unchanged in comparison with FIG. 13, while the sectional schematic diagram in the direction of B-B′ is as shown in FIG. 16.

S8: Depositing a source-drain metal layer on the etching barrier layer 9, and forming a source signal line 71 and a drain signal line 72 on the etching barrier layer 9 through an eighth patterning process. Specifically, one source-drain metal layer is deposited on a portion of the second insulating layer 6, on two end portions of the second active layer 8 and on the etching barrier layer 9 at first, then the source-drain metal layer is etched by using a preset mask, and a portion of the source-drain metal layer on the etching barrier layer 9 is etched off so as to form the source signal line 71 and the drain signal line 72 which are spaced from each other. The sectional schematic diagram of the obtained array substrate in the direction of A-A′ is as shown in FIG. 17, while the sectional schematic diagram in the direction of B-B′ remains unchanged in comparison with FIG. 16.

Further, at the same time of forming the source signal line 71 and the drain signal line 72 through the eighth patterning process in S8, the manufacturing method further includes a step of: forming a data signal line 7 (referring to FIG. 1, not shown in FIG. 2 and FIG. 3) in the same layer as the source signal line 71, and connecting the data signal line 7 to the source signal line 71.

Further, after the eighth patterning process in S8, the manufacturing method further includes steps S9 and S10.

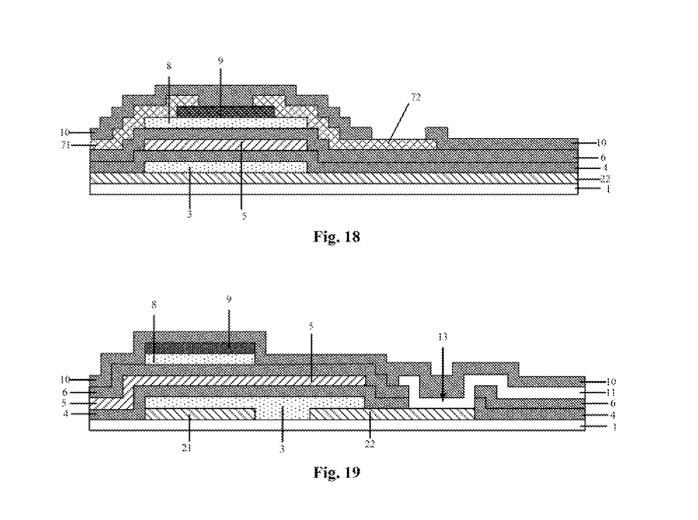

S9: Depositing an insulating layer on the source signal line 71 and the drain signal line 72 to form a third insulating layer 10, and forming a second via 14 at a position of the third insulating layer 10 corresponding to the drain signal line 72 through a ninth patterning process. The sectional schematic diagrams of the obtained array substrate in the direction of A-A′ and in the direction of B-B′ are as shown in FIG. 18 and FIG. 19, respectively.

S10: Depositing a known material layer of a pixel electrode on the third insulating layer 10, and forming a pixel electrode 12 on the third insulating layer 10 through a tenth patterning process, wherein the pixel electrode 12 is connected to the drain signal line 72 through the second via 14. The sectional schematic diagram of the obtained array substrate in the direction of A-A′ is as shown in FIG. 2, while the sectional schematic diagram in the direction of B-B′ is as shown in FIG. 3, and compared with FIG. 19, the pixel electrode 12 is added.

It should be noted that, both the first active layer 3 and the second active layer 8 in this embodiment are preferably oxide semiconductor layers. If both the first active layer 3 and the second active layer 8 are silicide semiconductor layers, it is further required to perform proper ion doping in portions near the two ends. If both the first active layer 3 and the second active layer 8 are oxide semiconductor layers, it is not required to perform ion doping.

The sectional schematic diagrams of the array substrate obtained by the above steps in the direction of A-A′ and in the direction of B-B′ are as shown in FIG. 2 and FIG. 3, respectively. Here, the data signal line 7 is connected to the pixel electrode through a second switch transistor to provide the pixel voltage, and the common signal line 2 (specifically the second common signal line 22) is connected to the common electrode 11 through the first switch transistor to provide the common voltage, so that a large driving voltage may be realized. In addition, the data signal line 7 and the common signal lines 2 share one gate 5, the pixel voltage and the common voltage of a single sub-pixel may be input simultaneously through a scanning signal without increasing the aperture ratio, so that the driving voltage may be provided according to the requirements.

### Embodiment 3

Embodiment 3 of the present invention provides a display device. The display device includes a color filter substrate, an array substrate and a liquid crystal layer filled between the color filter substrate and the array substrate, wherein the array substrate is the array substrate in Embodiment 1.

The display device in this embodiment may be any product or component having any display function, such as a TV set, a digital photo frame, a mobile phone, a tablet computer or the like.

The above implementations are merely used for explaining the present invention, but not intended to limit the present invention. Various modifications and variations may be made to the invention by those skilled in the art without departing from the spirit and scope of the present invention. These modifications and variations should be included in the protection scope of the present invention. The protection scope of the present invention should be defined by the claims.

1. A array substrate, comprising a substrate and common signal lines arranged on the substrate, wherein, the common signal lines comprise a first common signal line and a second common signal line which are spaced from each other, a first active layer for connecting the first common signal line and the second common signal line is arranged between the first common signal line and the second common signal line, the second common signal line is connected to a common electrode arranged above the second common signal line; and
a gate and a second active layer are sequentially arranged above the first active layer, a source signal line and a drain signal line are arranged on the second active layer, the drain signal line is connected to a pixel electrode arranged above the drain signal line

2. The array substrate according to claim 1, wherein, a first insulating layer is further arranged on the first active layer and beneath the gate.

3. The array substrate according to claim 2, wherein, a second insulating layer is further arranged on the gate and beneath the second active layer, a first via is arranged at positions of the first insulating layer and the second insulating layer corresponding to the second common signal line, and the second common signal line is connected to the common electrode through the first via.

4. The array substrate according to claim 3, wherein, a third insulating layer is further arranged on the source signal line and the drain signal line, a second via is arranged at a position of the third insulating layer corresponding to the drain signal line, and the drain signal line is connected to the pixel electrode through the second via.

5. The array substrate according to claim 4, wherein the common electrode is plate-shaped or strip-shaped, and the pixel electrode is strip-shaped.

6. The array substrate according to claim 1, wherein, an etching barrier layer is arranged on the second active layer and beneath the source signal line and the drain signal line, and the etching barrier layer covers the middle part of the second active layer.

7. The array substrate accordiong to claim 1, wherein both the first active layer and the second active layer are oxide semiconductor layers.

8. A manufacturing method of an array substrate, comprising steps of:
forming common signal lines on a substrate, wherein the common signal lines comprise a first common signal line and a second common signal line which are spaced from each other;
forming a first active layer between the first common signal line and the second common signal line, wherein the first active layer is used for connecting the first common signal line and the second common signal line;
sequentially forming a first insulating layer, a gate and a second insulating layer above the first active layer;
forming a second active layer above the gate;
forming an etching barrier layer on the second active layer;
forming a first via at positions of the first insulating layer and the second insulating layer corresponding to the second common signal line;
forming a common electrode on the second insulating layer, wherein the common electrode is connected to the second common signal line through the first via; and
forming a source signal line and a drain signal line on the etching barrier layer.

9. The manufacturing method according to claim 8, after the step of forming the source signal line and the drain signal line, further comprising steps of:
forming a third insulating layer on the source signal line and the drain signal line, and forming a second via at a position of the third insulating layer corresponding to the drain signal line; and
forming a pixel electrode on the third insulating layer, wherein the pixel electrode is connected to the drain signal line through the second via.

10. A display device, comprising a color filter substrate, an array substrate and a liquid crystal layer filled between the color filter substrate and the array substrate, wherein, the array substrate is the array substrate according to claim 1.

11. The display device according to claim 10 wherein, a first insulating layer is further arranged on the first active layer and beneath the gate.

12. The display device according to claim 11, wherein, a second insulating layer is further arranged on the gate and beneath the second active layer, a first via is arranged at positions of the first insulating layer and the second insulating layer corresponding to the second common signal line, and the second common signal line is connected to the common electrode through the first via.

13. The display device according to claim 12, wherein, a third insulating layer is further arranged on the source signal line and the drain signal line, a second via is arranged at a position of the third insulating layer corresponding to the drain signal line, and the drain signal line is connected to the pixel electrode through the second via.

14. The display device according to claim 13, wherein the common electrode is plate-shaped or strip-shaped, and the pixel electrode is strip-shaped.

15. The display device according to claim 10, wherein, an etching barrier layer is arranged on the second active layer and beneath the source signal line and the drain signal line, and the etching barrier layer covers the middle part of the second active layer.

16. The display device according to claim 10, wherein both the first active layer and the second active layer are oxide semiconductor layers.
